(19) United States
(12) Patent Application Publication
(10) Pub. No.: US 2025/0120053 A1
(43) Pub. Date: Apr. 10, 2025

(54) POWER SUPPLY AND METHOD FOR OPERATING A POWER SUPPLY

(71) Applicant: TRUMPF HÜTTINGER GMBH + CO. KG, Freiburg (DE)

(72) Inventor: Clemens REHBEIN, Auggen (DE)

(21) Appl. No.: 18/905,165

(22) Filed: Oct. 3, 2024

Related U.S. Application Data
(63) Continuation of application No. PCT/EP2023/058711, filed on Apr. 3, 2023.

(30) Foreign Application Priority Data
Apr. 4, 2022 (DE) 10 2022 108 022.6

(51) Int. Cl. H05K 7/20

(52) U.S. Cl. CPC H05K 7/20945; H05K 7/20927

(57) ABSTRACT

A method for operating a heavy-duty component includes determining a first quantity of heat created by the heavy-duty component, determining a second quantity of heat that is capable of being dissipated by a volume flow of a coolant, determining a difference between the first and second quantities of heat, and based on the difference, at a first operating point at which the second quantity of heat is greater than the first quantity of heat, reducing the volume flow, at a second operating point at which the second quantity of heat is less than the first quantity of heat, increasing the volume flow, and at a third operating point at which a third quantity of heat that is capable of being dissipated by a maximum volume flow of the coolant is less than or equal to the first quantity of heat, reducing the first quantity of heat that is created.

### CROSS REFERENCE TO RELATED APPLICATIONS

This application is a U.S. National Phase application under 35 U.S.C. § 371 of International Application No. PCT/EP2023/058711, filed on Apr. 3, 2023, and claims benefit to German Patent Application No. DE 10 2022 108 022.6, filed on Apr. 4, 2022. The International Application was published in German on Oct. 12, 2023 as WO 2023/194322 A1 under PCT Article 21(2).

### FIELD

Embodiments of the present invention relate to a method for operating a power supply.

### BACKGROUND

A power supply of this type supplies a consumer with electrical power at a voltage, frequency or current intensity that is known, but possibly variable during operation. From a power typically above 500 W, as is used e.g. in industrial processes for generating laser radiation in gas lasers or plasma or for induction heating, a power supply of this type also has, in addition to simple electrical components, heavy-duty electrical components which can be combined as desired and depending on the requirements to form a heavy-duty electrical assembly. Power supplies of this type are often cooled with the aid of liquid cooling. Production facilities that make use of the aforementioned processes, for example a production facility for semiconductor components, are often equipped with a plurality of systems which can in turn have a plurality of power supplies and other devices or systems that are to be cooled with liquid. Overall, these production facilities often require large quantities of water or other liquids for cooling. A reduction in coolant consumption is therefore desired economically and ecologically.

### SUMMARY

Embodiments of the present invention provide a method for operating a heavy-duty component. The method includes determining a first quantity of heat created by the heavy-duty component, determining a second quantity of heat that is capable of being dissipated by a volume flow of a coolant, determining a difference between the first quantity of heat and the second quantity of heat, and based on the difference of the first quantity of heat and the second quantity of heat, at a first operating point at which the second quantity of heat is greater than the first quantity of heat, reducing the volume flow, at a second operating point at which the second quantity of heat is less than the first quantity of heat, increasing the volume flow, and at a third operating point at which a third quantity of heat that is capable of being dissipated by a maximum volume flow of the coolant is less than or equal to the first quantity of heat that is created, reducing the first quantity of heat that is created.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a power supply according to embodiments of the invention having temperature measurement at the inlet and outlet;

FIG. 2 shows a further configuration of the temperature sensor according to some embodiments;

FIG. 3 shows a flowchart of a method according to embodiments of the invention for operating a power supply;

FIG. 4 shows an arrangement in which the temperature at a heavy-duty assembly is recorded according to some embodiments;

FIG. 5 shows a power supply according to embodiments of the invention having temperature measurement and air humidity measurement; and

FIG. 6 shows a power supply located in a switchgear cabinet according to some embodiments.

### DETAILED DESCRIPTION

Embodiments of the present invention provide a method and a device of a power supply, by means of which the required quantity of the coolant can be reduced and at the same time damage due to water precipitating out of the humid air can be prevented.

A method is provided for operating a heavy-duty component, in particular a power supply, which can provide a power greater than 500 W, wherein the method has the following steps:
a. determining the quantity of heat created by the heavy-duty component,
b. determining the quantity of heat that can be dissipated by the coolant flow,
c. determining the difference between the quantity of heat that is created and that can be dissipated, and
d. on the basis of the analysis of the difference of the quantities of heat,
i. at a first operating point at which the volume flow of the coolant is able to dissipate a quantity of heat that is larger than the quantity of heat that is created, reducing the volume flow of the coolant,
ii. at a second operating point at which the volume flow of the coolant is able to dissipate a quantity of heat that is smaller than the quantity of heat that is created, increasing the volume flow,
iii. at a third operating point at which the maximum volume flow of the coolant is not able to dissipate a quantity of heat that is larger than or equal to the quantity of heat that is created, reducing the quantity of heat created, in particular by reducing the output power of the heavy-duty component, in particular by switching off the heavy-duty component, and/or outputting a warning.

The quantities of heat, in particular the quantity of heat that can be dissipated by the coolant flow and the heat created by operating the power supply, can be calculated for this method. The quantity of heat created can be calculated by means of power input and efficiency or power input and power output of the heavy-duty assembly. Also, the quantity of heat created can for example be determined by means of stored data for the quantity of heat for different power inputs. Furthermore, the quantity of heat created can be determined by means of the temperature difference upstream and downstream of the heavy-duty assembly and the volume flow of the coolant. The quantity of heat that can be dissipated can be determined by means of the measured volume flow of the coolant or on the basis of the valve position and/or other variables, such as e.g. the estimated volume flow and the temperature of the coolant, in particular at the inlet, and/or the comparison with stored substance data.

The object is also achieved by a method in which, in an additional method step, the valve control reduces the volume flow of the coolant in such a manner that, e.g. in the case of low heat generation and low temperature of the heavy-duty assembly, in particular in the spatial vicinity of the heavy-duty assembly, no water precipitates out of the humid air.

In this case, the valve control can determine whether water is precipitating out of the air, e.g. by way of substance data of humid air being compared with the given air humidity and the temperature of the coolant flow. Alternatively or additionally, it is possible to compare one or more of the previously mentioned data with one or more of the following data records for this: the temperature of the heat sink, which e.g. is measured, the temperature of the heavy-duty assembly, which e.g. is measured, the calculation of the temperature of a component for example by means of power inflow, efficiency and heat dissipation or other data, e.g. by means of calculation on the basis of further data. A comparison of actual values with desired values that are for example stored on a storage medium is also conceivable.

For this, the device may additionally have a device for measuring the air humidity in the vicinity of the heavy-duty assembly.

Furthermore, it is advantageous if the valve control determines that water is precipitating in spite of reduction of the coolant flow, and the valve control activates the power supply in such a manner that this power supply adjusts the operation.

The object is also achieved by a method in which control of the valve and therefore of the volume flow of the coolant takes place directly by means of the difference of temperature values. In this case, starting from a minimum throughflow, it is possible to determine how the temperature of the coolant flow at the outlet minus the temperature of the coolant flow at the inlet develops over time. If this difference increases and the temperature at the outlet is at a level above an upper threshold, the valve is activated in such a manner that the volume flow of the coolant is increased and thus a greater cooling power is achieved. If this difference decreases for example and, at the same time, the temperature at the outlet is at a level that is below a lower threshold, the valve is activated in such a manner that the volume flow of the coolant is reduced.

The object is also achieved by a method in which, in a first method step, the temperature is determined not exclusively on the flow of the coolant, but rather the valve control is carried out on the basis of temperature measured values at the outlet of the coolant flow and by measuring the temperature of the heavy-duty assembly, and, in a second method step, the formation of the difference of the two values is carried out, and, in a third method step, the valve control activates the valve on the basis of this difference.

The object is also achieved by a control device having two temperature measuring devices, a valve that is suitable for restricting the coolant flow completely, and a valve control, wherein this activates the valve in such a manner that
a) at a first operating point at which the volume flow of the coolant is able to dissipate a quantity of heat that is larger than the quantity of heat that is created, the volume flow of the coolant is reduced,
b) at a second operating point at which the volume flow of the coolant is able to dissipate a quantity of heat that is smaller than the quantity of heat that is created, the volume flow is increased,
c) at a third operating point at which the maximum volume flow of the coolant is not able to dissipate a quantity of heat that is larger than or equal to the quantity of heat that is created, the control device is set up to reduce the quantity of heat created, in particular by reducing the output power of the heavy-duty component, in particular by switching off the heavy-duty component, and/or outputting a warning.

Furthermore, the object is achieved by a power supply, which can provide a power greater than 500 W, having at least one heavy-duty electrical assembly which can generate heat during continuous operation, a heat sink which is able to carry a coolant, a control device comprising at least two temperature measuring devices, a valve which is suitable for restricting the coolant flow completely, and a valve control, wherein this valve control activates the valve in such a manner that, at a first operating point at which the volume flow of the coolant is able to dissipate a quantity of heat that is larger than the quantity of heat that is created, the volume flow of the coolant through the heat sink is reduced, and, at a second operating point at which the volume flow of the coolant is able to dissipate a quantity of heat that is smaller than the quantity of heat that is created, activates the valve in such a manner that the volume flow of the coolant through the heat sink is increased, and, at an operating point at which the maximum volume flow of the coolant is not able to dissipate a quantity of heat that is larger than or equal to the quantity of heat that is created, a control device is set up to activate the power supply in such a manner that the quantity of heat created is reduced, in particular by reducing the output power of the power supply, in particular by switching off the power supply, and/or outputting a warning.

Embodiments of the present invention also provide a power supply, wherein the power supply is located in a housing, in particular in a switchgear cabinet. As a result, the regulation of the temperature can be improved, in particular at a high ambient temperature and high air humidity.

The following description serves to explain embodiments of the invention in greater detail in association with the drawings. Individual features of these exemplary embodiments can also further develop the previously described methods or devices according to the invention separately from other features of the respective exemplary embodiments.

Elements that are the same or have equivalent functions are denoted by the same reference signs in all the exemplary embodiments.

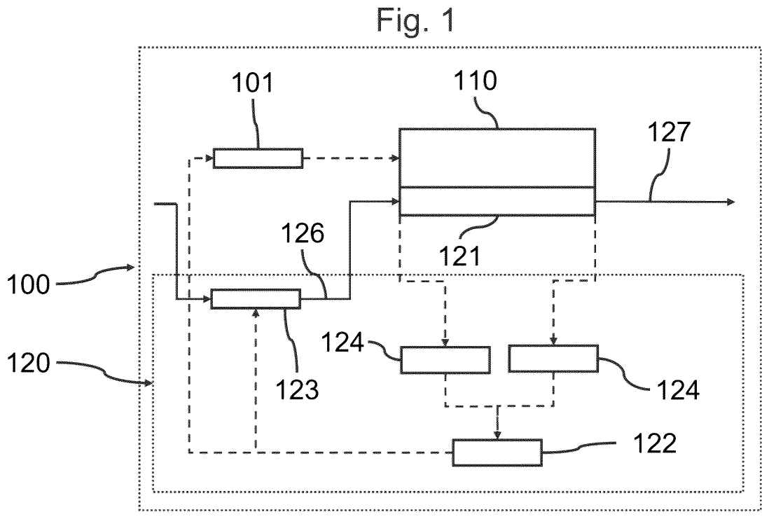

FIG. 1 shows a power supply 100 having temperature measurement at the inlet and outlet of the coolant flow. The power supply 100 consists of at least three main constituents: a heavy-duty assembly 110, a heat sink 121 and a control device 120. The heat sink 121 has a coolant inlet 126 and a coolant outlet 127. The heavy-duty assembly 110 generates heat during operation. In order to avoid a temperature increase to the extent that the heavy-duty assembly 110 can be damaged, excessive heat is dissipated by the heat sink 121. For this, the heat sink 121 can, as shown in this embodiment, be connected to the heavy-duty assembly 110 directly. The heat sink 121 is able to carry a coolant, for which the heat sink can have a cavity. If coolant flows through this cavity, the direction of flow defines one opening of this cavity as inlet and a different opening as outlet. The direction of flow of the coolant is identified in FIG. 1 by simple arrows with a corresponding label for inlet and outlet. By means of one temperature measuring device 124 at the inlet and at the outlet of the heat sink 121 in each case, the temperature at these locations in the coolant flow can be collected. The locations for measuring the temperature of the coolant may however also be at other locations along the coolant flow, in particular in the direction of flow upstream and downstream of the location at which the heavy-duty assembly 110 emits heat to the heat sink 121. The recorded temperatures are processed in the valve control 122. On the basis of this processing, the valve 123 can be activated by the valve control 122. The valve 123 is used for regulating the volume flow of the coolant. In this case, the valve 123 can restrict the flow of the coolant completely. Also, the valve control 122 may be able to transmit a signal to the power supply control 101. The power supply can be controlled by means of the power supply control 101, in particular the operating state and power that is output.

Generally, such power supplies are operated in a manner in which large quantities of heat are created, which makes liquid cooling necessary. In this case however, the operation does not have only one single operating point. Thus, a plurality of operating points are conceivable within an application, which operating points differ with regards to the required power and cooling output. In this case, at an operating point at maximum power, maximum cooling is necessary in order to protect the components and the entire power supply from damage. At a different operating point by contrast, a low power can flow through the power supply. A significantly lower quantity of heat is created in this case. Consequently, a lower cooling output is also necessary, because even a smaller quantity of heat must be dissipated.

In addition, there is the risk that, when cooling a heavy-duty assembly that outputs only very small quantities of heat, because this heavy-duty assembly is loaded with low power at the given operating point, the temperature of a component or the entire assembly decreases below the temperature of the ambient air due to the dissipation of heat. In this case, it is possible that water that is found in the air in the form of water vapor precipitates and is deposited on the electrical components of the heavy-duty assembly in the form of liquid water. As a result, damage to this heavy-duty assembly may occur due to undesired current flows through the water or due to corrosion. Both patterns of damage entail the risk that the entire power supply is irreparably damaged. In this case, the power supply is able to control the cooling at the individual operating points independently of one another.

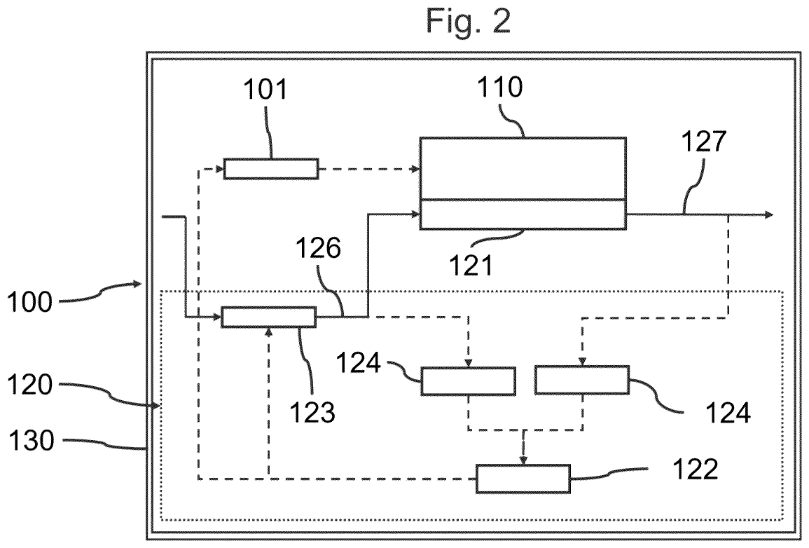

FIG. 2 shows a power supply 100 having temperature measurement at the inlet and outlet of the coolant flow. In this embodiment, the temperature measuring devices 124 are not in the direct vicinity of the component that is to be cooled. According to this principle, different positionings can be chosen for the recording of the temperature of the coolant in the coolant flow by the temperature measuring devices 124.

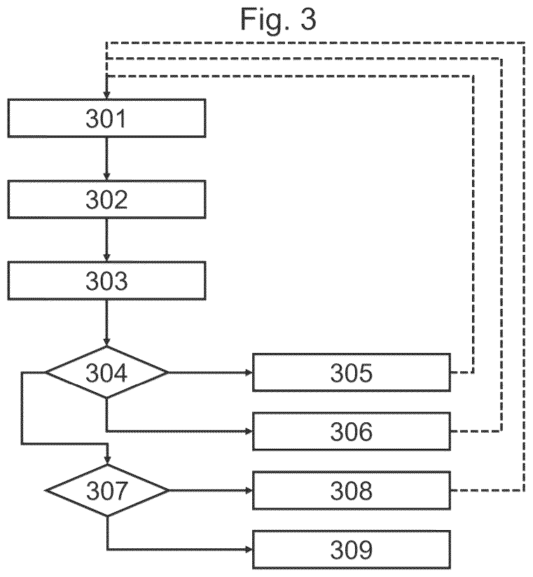

FIG. 3 shows a flowchart of a method for operating a power supply 100 having a power of at least 500 W. The power supply unit 100 has a heat sink 121 which was integrated into the power supply 100 for cooling a heavy-duty electrical assembly 110. A coolant, for example water or a dielectric fluid, can to this end flow through the heat sink 121. In a first method step 301, the temperature is measured at the inlet of the heat sink 121 and at the outlet of the same. This takes place by means of one temperature measuring device 124 in each case. The difference between these temperatures is calculated in a second method step 302. In the third method step 303, a valve control 122 analyzes the temperature difference. In an analysis 304, a valve 123 is activated based on the result of the analysis. If it is determined by means of the valve control 122 that the volume flow at the given temperature difference can dissipate a quantity of heat that is larger than the quantity of heat of the heavy-duty assembly 110 that is currently being generated, the valve 123 is activated in a method step 305, in order to reduce the volume flow of the coolant. If it is determined by means of the valve control 122 that the volume flow at the given temperature difference can dissipate a quantity of heat that is smaller than the quantity of heat of the heavy-duty assembly 110 that is currently being generated, the valve 123 is activated in a method step 306, in order to increase the volume flow of the coolant. If it is determined by means of the valve control 122 in method step 304 that the volume flow at the given temperature difference can dissipate a quantity of heat that is smaller than the quantity of heat of the heavy-duty assembly 110 that is currently being generated and that the volume flow of the coolant cannot be increased further, the power supply control 101 is activated in order to reduce the quantity of heat that is created, for example in a method step 308 by reducing the power of the heavy-duty assembly 110 or in a method step 309 by switching off the power supply unit 110. Before that, in a method step 307, it is determined whether the reduction of the quantity of heat that is created should take place by reducing the power of the heavy-duty assembly 110 or by switching off the power supply unit 110.

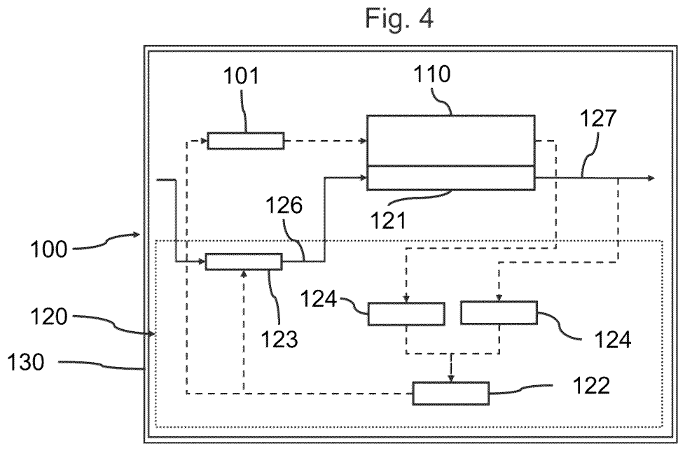

FIG. 4 shows a power supply unit 100, in which the temperature is measured by a temperature measuring device 124 at the outlet of the coolant flow and at the heavy-duty assembly 110. These measured temperature values can be analyzed in the valve control 122, in order to activate the valve 123 or the power supply control 101 based on the result.

The advantage of this embodiment is the exact reaction due to the frequent presence of a temperature measuring device 124 for recording measured temperature values of heavy-duty assemblies 110 in power supplies 100.

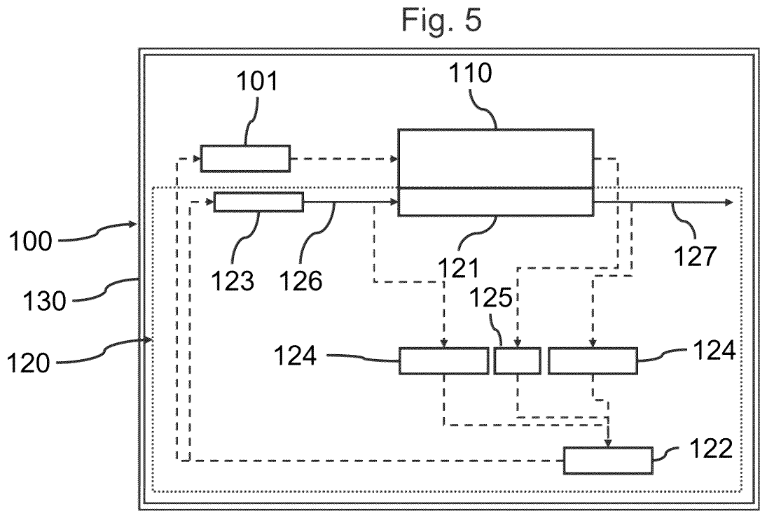

FIG. 5 shows a further embodiment of a power supply 100. In addition to two temperature measuring devices 124, this embodiment has an air-humidity measuring device 125. The temperature measuring devices 124 determine the temperature of the coolant at the inlet and outlet of the coolant flow of the heat sink 121. The air-humidity measuring device 125 can determine the air humidity in the direct vicinity of the heavy-duty assembly 110. Likewise, an embodiment is conceivable, in which the air humidity is determined in direct spatial proximity to the heat sink 121 solely or in addition to the proximity to the heavy-duty assembly 110. On the basis of the air humidity and the temperatures, the valve control 122 can determine whether water is precipitating in proximity to the heavy-duty assembly 110, in particular on the surface of the heavy-duty assembly 110 or the surface of the heat sink 121 that faces in the direction of the heavy-duty assembly 110.

To this end, a temperature of the heavy-duty assembly 110 can also be determined by the valve control, be it by recording the temperature by means of a corresponding device, by a combination of power outflows and power inflows or by a different method.

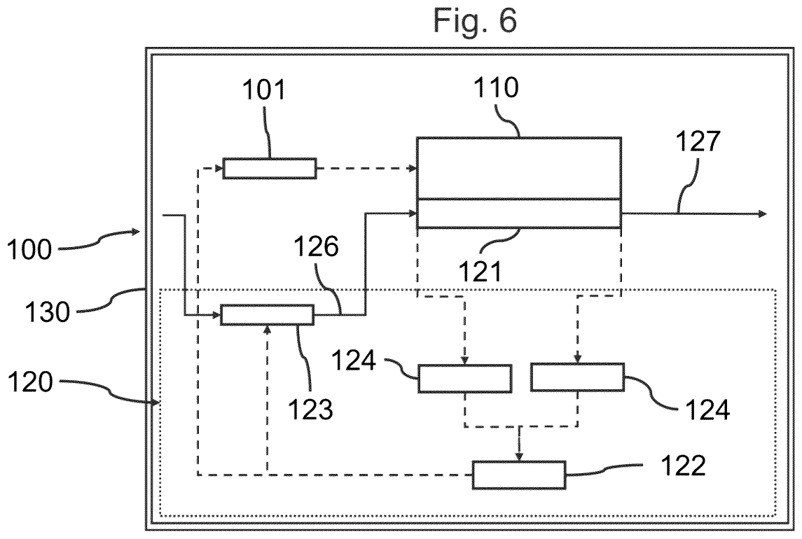

FIG. 6 shows a power supply 100 which is located in a switchgear cabinet 130. In this case, all elements of the power supply 100, like the control device 120 also, are enclosed by the switchgear cabinet 130. The housing may be relevant for the cooling performance and the air humidity in particular. If humid air, in particular with high relative humidity and, compared to the coolant temperature at the inlet, high temperature, is located in the switchgear cabinet 130, water may rapidly precipitate out of the humid air. This may precipitate in the form of dew, in the case of a relatively large quantity in the form of water droplets, on the heat sink and in the surroundings thereof. Due to the direct thermal contacting between the heavy-duty assembly 110 and the heat sink 121, the heavy-duty assembly 110 in the low power state, in particular in the switched-off state, can take on the temperature of the heat sink 121 or get very close to this. As a result, dew may also be deposited on the heavy-duty assembly 110. Embodiments of the invention can counteract that in a suitable manner.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

100 Power supply
101 Power supply control
110 Heavy-duty assembly
120 Control device
121 Heat sink
122 Valve control
123 Valve
124 Temperature measuring device
125 Air-humidity measuring device
130 Switchgear cabinet
126 Coolant inlet
127 Coolant outlet

1. A method for operating a heavy-duty component, the method comprising:
determining a first quantity of heat created by the heavy-duty component,
determining a second quantity of heat that is capable of being dissipated by a volume flow of a coolant,
determining a difference between the first quantity of heat and the second quantity of heat, and
based on the difference of the first quantity of heat and the second quantity of heat,
at a first operating point at which the second quantity of heat is greater than the first quantity of heat, reducing the volume flow,
at a second operating point at which the second quantity of heat is less than the first quantity of heat, increasing the volume flow, and
at a third operating point at which a third quantity of heat that is capable of being dissipated by a maximum volume flow of the coolant is less than or equal to the first quantity of heat that is created, reducing the first quantity of heat that is created.

2. The method as claimed in claim 1, wherein the second quantity of heat that is capable of being dissipated by the volume flow is determined from a difference of two temperatures of the coolant.

3. The method as claimed in claim 1, wherein the second quantity of heat that is capable of dissipated is determined from at least one temperature of the coolant and the volume flow.

4. The method as claimed in claim 1, wherein the second quantity of heat that is capable of being dissipated by the volume flow is determined from at least one temperature of the coolant and a position of an inlet valve.

5. The method as claimed in claim 1, wherein the difference between the first quantity of heat and the second quantity of heat is determined from a difference of a temperature of the heavy-duty component and a temperature of the coolant downstream of the heavy-duty component.

6. A method for operating a heavy-duty component, the method comprising:
determining a first temperature of a coolant in a direction of flow upstream of the heavy-duty component,
determining a second temperature of the coolant in the direction of flow downstream of the heavy-duty component,
determining a difference between the first temperature and the second temperature, and
based on the difference between the first temperature and the second temperature,
at a first operating point at which a volume flow of the coolant is capable of dissipating a first quantity of heat that is greater than a quantity of heat that is created, reducing the volume flow of the coolant,
at a second operating point at which the volume flow of the coolant capable of dissipating a second quantity of heat that is less than the quantity of heat that is created, increasing the volume flow, and
at a third operating point at which a maximum volume flow of the coolant capable of dissipating a third quantity of heat that is less than or equal to the quantity of heat that is created, reducing the quantity of heat that is created.

7. (canceled)

8. The method as claimed in claim 1, further comprising:
determining an air humidity in proximity to the heavy-duty component, and
upon determining that, due to a low temperature of the heavy-duty component and/or of the volume flow of the coolant, water is precipitating or is threatening to precipitate out of air in proximity to the heavy-duty component, reducing the volume flow of the coolant in such a manner that no water precipitates out of the air.

9. The method as claimed in claim 8, further comprising, upon determining that water is precipitating in spite of the reduction of the coolant flow, adjusting operation of the heavy-duty component.

10. The method as claimed in claim 8, wherein whether water is precipitating out of the air is determined prior to supplying the heavy-duty component with voltage.

11. A control device for controlling a volume flow of a coolant for cooling a heavy-duty component, the control device comprising two temperature measuring devices, a valve that is configured for regulating the volume flow of the coolant, and a valve control, wherein the valve control activates the valve in such a manner that
at a first operating point at which the volume flow of the coolant is capable of dissipating a first quantity of heat that is greater than a quantity of heat that is created by the heavy-duty component, the volume flow of the coolant is reduced, and
at a second operating point at which the volume flow of the coolant is capable of dissipating a second quantity of heat that is less than the quantity of heat that is created by the heavy-duty component, the volume flow is increased,
wherein, at a third operating point at which a maximum volume flow of the coolant is capable of dissipating a third quantity of heat that is less than or equal to the quantity of heat that is created, the control device is configured to reduce the quantity of heat created by the heavy-duty component.

12. The control device as claimed in claim 11, wherein a first temperature measuring device of the two temperature measuring devices is arranged upstream of the valve in a coolant flow direction, and a second temperature measuring device of the two temperature measuring devices is arranged downstream of the valve in the coolant flow direction.

13. The method as claimed in claim 1, wherein the reducing the first quantity of heat comprises reducing an output power of the heavy-duty component.

14. The method as claimed in claim 1, wherein the reducing the first quantity of heat comprises switching off the heavy-duty component.

15. The method as claimed in claim 1, further comprising, upon determining that, at the third operating point at which the third quantity of heat is less than or equal to the first quantity of heat, outputting a warning.
